(19) United States
(12) Patent Application Publication
(10) Pub. No.: US 2025/0221118 A1
(43) Pub. Date: Jul. 3, 2025

(54) DISPLAY DEVICE

(71) Applicant: AUO Corporation, Hsinchu City (TW)

(72) Inventors: Shih-Ming HUANG, Hsinchu City (TW); Chi-Jui CHANG, Hsinchu City (TW); Chun-Wei HUANG, Hsinchu City (TW); Chung-Chih WU, Hsinchu City (TW); Yu-Hsin HUANG, Hsinchu City (TW); Kuan-Heng LIN, Hsinchu City (TW)

(21) Appl. No.: 18/932,170

(22) Filed: Oct. 30, 2024

(30) Foreign Application Priority Data
Dec. 29, 2023 (TW) 11215742

(51) Int. Cl. H01L 33/60; H01L 25/075; H01L 33/48

(52) U.S. Cl. CPC H10H 20/856; H01L 25/0753; H10H 20/8506

(57) ABSTRACT

A display device includes a display substrate and a transparent cover. The display substrate includes a plurality of pixel components arranged in an array. Each pixel component includes a micro light-emitting diode (LED), a reflective material, a first refractive material and a second refractive material. The reflective material is provided with a groove. An upper surface of the micro LED is exposed in the groove. The first refractive material is located in the groove and covers the upper surface of the micro LED. The second refractive material is located in the groove and covers the first refractive material. An interface between the first and second refractive materials is a curved surface. The transparent cover covers the display substrate. A third refractive region is formed between the transparent cover and the second refractive material. Light emission of the display device in a first direction and in a second direction is asymmetrical.

### CROSS-REFERENCE TO RELATED PATENT APPLICATION

This non-provisional application claims priority to and the benefit of, pursuant to 35 U.S.C. § 119 (a), patent application Serial No. 112151742 filed in Taiwan on Dec. 29, 2023. The disclosure of the above application is incorporated herein in its entirety by reference.

Some references, which may include patents, patent applications and various publications, are cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference were individually incorporated by reference.

### FIELD

The present disclosure relates to the field of displays, and particularly to a display device with an asymmetrical light emission viewing angle.

### BACKGROUND

The background description provided herein is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

In the field of displays, a light-emitting diode (LED) is gradually replacing the backlight module due to its advantages such as high brightness and small size. However, in certain products, the use of LED light-emitting components also brings specific issues.

For example, currently, the LED is a point light source, which typically emits light uniformly in all directions. However, when used in an automotive display, such as a heads-up display, when the LED emits light at a large angle and projects on the windshield, the image generated may obstruct the front view of the driver, thus affecting driving safety.

### SUMMARY

The present disclosure provides a display device. In certain embodiments, the display device includes a display substrate and a transparent cover. The display substrate includes a plurality of pixel components arranged in an array. Each pixel component has a first side and a second side, and a length of the first side is greater than a length of the second side.

Each pixel component includes a micro light-emitting diode (LED), a reflective material, a first refractive material and a second refractive material. The reflective material is located on the display substrate and is provided with a groove. An upper surface of the micro LED is exposed in the groove. The first refractive material is located in the groove and covers the upper surface of the micro LED. The second refractive material is located in the groove and covers the first refractive material. The groove has a central axis, a depth of the groove decreases by moving away from the central axis, and the central axis is parallel to a first direction. The transparent cover covers the display substrate, and a third refractive region is formed between the transparent cover and the second refractive material.

A refractive index of the second refractive material is greater than a refractive index of the first refractive material, and a difference value the refractive index of the first refractive material and the refractive index of the second refractive material is 0.3 to 0.6. Light emission of the display device in the first direction and in a second direction perpendicular to the first direction is asymmetrical.

In certain embodiments, a width of the groove decreases from a first surface of the reflective material toward the micro LED. More specifically, in certain embodiments, the groove is in a parabolic surface from the first surface of the reflective material toward an edge of the micro LED.

In certain embodiments, a boundary between first refractive material and the second refractive material is in a hyperbolic surface, a parabolic surface, an elliptical surface, or a spherical surface.

In certain embodiments, the refractive index of the first refractive material is 1.4 to 1.7.

In certain embodiments, the refractive index of the second refractive material is 1.4 to 2.0. More specifically, in certain embodiments, the refractive index of the second refractive material is 1.8 to 1.95.

In certain embodiments, the third refractive region is a cavity.

In certain embodiments, the third refractive region is filled with a third refractive material, and a refractive index of the third refractive material is less than the refractive index of the second refractive material. More specifically, in certain embodiments, the refractive index of the third refractive material is 1.2 to 1.6.

More specifically, in certain embodiments, a top surface of the third refractive material and a first surface of the reflective material are coplanar.

In certain embodiments, a maximum full width at half maximum (FWHM) angle of a light intensity distribution in the second direction is less than or equal to +/−20 degrees.

In certain embodiments, a FWHM angle of a light intensity distribution in the first direction is greater than or equal to +/−40 degrees.

In certain embodiments, each of the pixel components has a first side and a second side, a length of the first side is greater than a length of the second side, the first side is parallel to the first direction, and the second side is parallel to the second direction.

In certain embodiments, a length of a perpendicular projection of the groove onto the transparent cover in the first direction is greater than a length of the perpendicular projection in the second direction.

As shown in each of the aforementioned embodiments, by utilizing an anisotropic groove combined with the arrangement of the first refractive material and the second refractive material, the light emission of the display device in the first direction and in the second direction may be asymmetrical, allowing the display device to be applied in electronic devices that require a narrow viewing angle in a specific direction.

These and other aspects of the present disclosure will become apparent from the following description of the embodiment taken in conjunction with the following drawings, although variations and modifications therein may be effected without departing from the spirit and scope of the novel concepts of the disclosure.

### BRIEF DESCRIPTION OF THE DRAWINGS

The accompanying drawings illustrate one or more embodiments of the disclosure and together with the written description, serve to explain the principles of the disclosure. Wherever possible, the same reference numbers are used throughout the drawings to refer to the same or like elements of an embodiment, and wherein:

FIG. 1 is a perspective view of a display device according to one embodiment of the present disclosure.

FIG. 2 is a sectional view of a pixel component according to a first embodiment of the present disclosure.

FIG. 3A is a light-emitting intensity-angle distribution diagram of a display device according to one embodiment of the present disclosure.

FIG. 3B is a light-emitting intensity mapping diagram of a display device according to one embodiment of the present disclosure.

FIG. 4 is a sectional view of a pixel component according to a second embodiment of the present disclosure.

FIG. 5 is a sectional view of a pixel component according to a third embodiment of the present disclosure.

FIG. 6 is a sectional view of a pixel component according to a fourth embodiment of the present disclosure.

FIG. 7 is a sectional view of a pixel component according to a fifth embodiment of the present disclosure.

FIG. 8 is a sectional view of a pixel component according to a sixth embodiment of the present disclosure.

### DETAILED DESCRIPTION

It should be understood that when one component is referred to as being disposed “on” the other component, the component may be directly disposed on the other component, or an intermediate component may also exist between the two components, and the component is connected to the other component through the intermediate component. In contrast, when one component is referred to as being “directly disposed on the other component” or “directly disposed to the other component,” it should be understood that no intermediate component exists therebetween.

Further, the terms “first”, “second”, “third” etc. may be used herein to distinguish one element, component, region, layer or portion from another element, component, region, layer or portion, without representing the required sequence thereof. Furthermore, relative terms, such as “lower” or “bottom” and “upper” or “top”, may be used herein to describe one element's relationship to another element. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The relative terms merely represent the relative orientations, and not the absolute orientations.

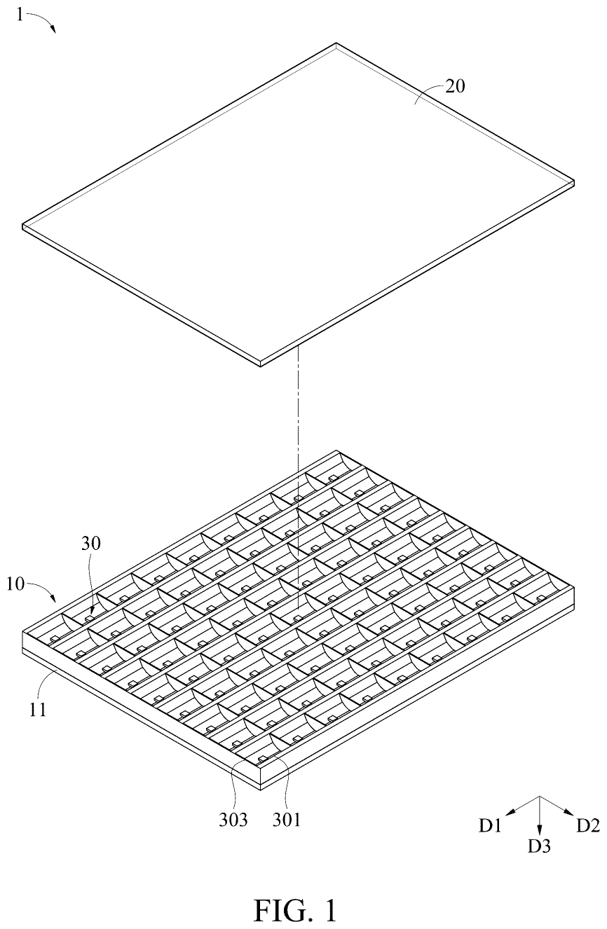

FIG. 1 is a perspective view of a display device according to one embodiment of the present disclosure. As shown in FIG. 1, in certain embodiments, the display device 1 includes a display substrate 10 and a transparent cover 20. The display substrate 10 includes a plurality of pixel components 30 arranged in an array. In other words, the pixel components 30 are in a rectangular shape. The transparent cover 20 covers the display substrate 10. In certain embodiments, each pixel component 30 has a first side 301 and a second side 303, and a length of the first side 301 is greater than a length of the second side 303.

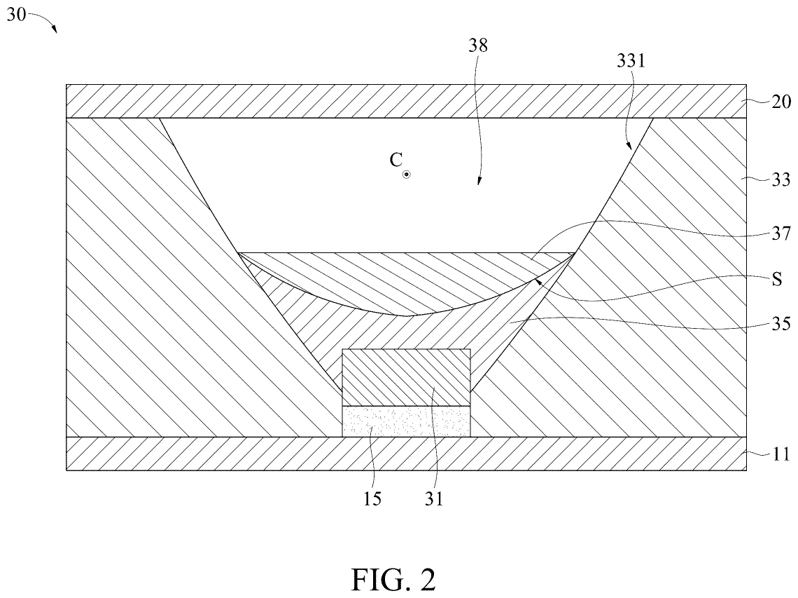

FIG. 2 is a sectional view of a pixel component according to a first embodiment of the present disclosure. Simultaneously referring to FIG. 1, FIG. 2 is a sectional view of FIG. 1 along a second direction D2 (hereinafter the Y direction) and a third direction D3 (hereinafter the Z direction). Simultaneously referring to FIG. 1, as shown in FIGS. 1 and 2, each pixel component 30 includes a micro LED 31, a reflective material 33, a first refractive material 35 and a second refractive material 37. The micro LED 31 is disposed on a substrate 11 through a conductive material 15, and the micro LED 31, the conductive material 15 and the substrate 11 are portions of the display substrate 10. In addition, in each pixel component 30, the reflective material 33 is located on the micro LED 31, and only a partial section thereof is shown herein. However, it should be understood that the reflective material 33 covers the display substrate 10 in a layered shape. The reflective material 33 is provided with a groove 331. The reflective material 33 covers an upper surface of the substrate 11, the conductive material 15, and a portion of the micro LED 31. An upper surface of the micro LED 31 is exposed in the groove 331. The groove 331 has a central axis C, a depth of the groove 331 decreases by moving away from the central axis C, and the central axis C is parallel to a first direction D1.

Herein, a length of a perpendicular projection of the groove 331 onto the transparent cover 20 in the first direction D1 (hereinafter the X direction) is greater than a length of the perpendicular projection in the second direction D2. The first direction D1 is parallel to the first side 301, and the second direction D2 is parallel to the second side 303.

The first refractive material 35 is located in the groove 331 and covers the upper surface of the micro LED 31. The second refractive material 37 is located in the groove 331 and covers the first refractive material 35. An interface S between the first refractive material 35 and the second refractive material 37 is a curved surface. In addition, a third refractive region 38 is formed between the transparent cover 20 and the second refractive material 37.

Herein, a refractive index of the second refractive material 37 is 1.4 to 2.0, the refractive index of the second refractive material 37 is greater than a refractive index of the first refractive material 35, and a difference value the refractive index of the first refractive material 35 and the refractive index of the second refractive material 37 is 0.3 to 0.6. In certain embodiments, the refractive index of the first refractive material 35 may be selectively 1.4 to 1.7, and the refractive index of the second refractive material 37 is 1.8 to 1.95. In the embodiment as shown in FIG. 2, the center of the third refractive region 38 is a cavity, where only air exists in the third refractive region 38, and the refractive index of the third refractive region 38 is substantially 1. Thus, light emission of the display device in the first direction D1 and in the second direction D2 is asymmetrical, thereby allowing the display device to be applied in an electronic device that requires a narrow viewing angle in a specific direction, such as a vehicle projection display.

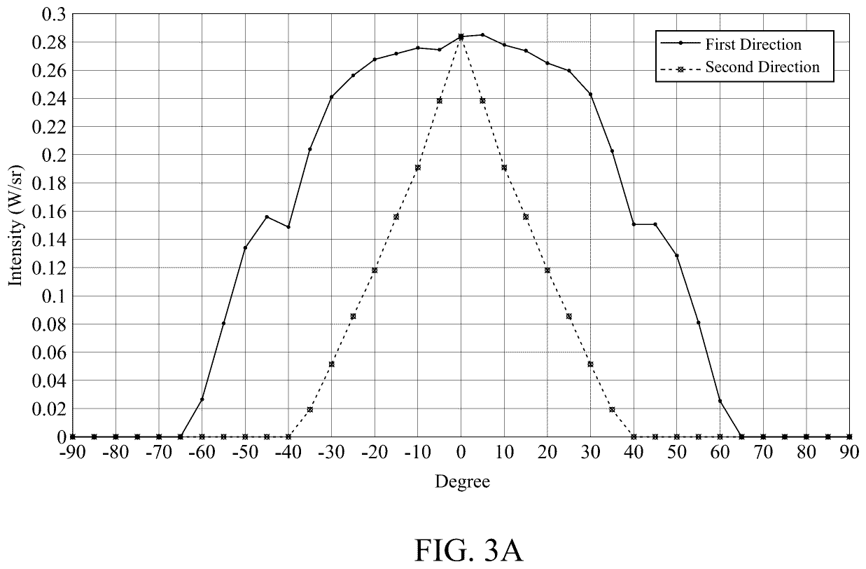

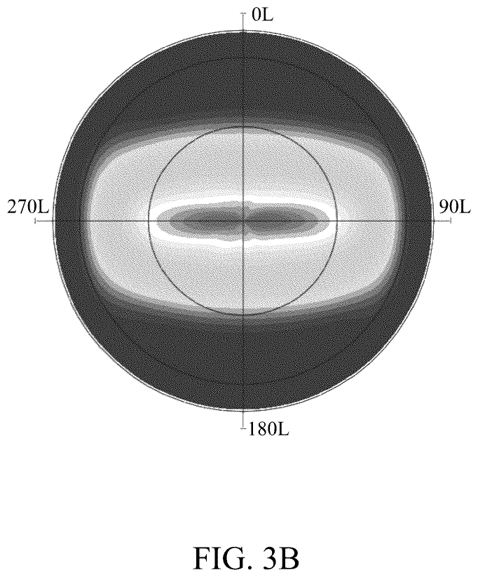

FIG. 3A is a light-emitting intensity-angle distribution diagram of a display device according to one embodiment of the present disclosure. FIG. 3B is a light-emitting intensity mapping diagram of a display device according to one embodiment of the present disclosure. A maximum full width at half maximum (FWHM) angle of a light intensity distribution in the second direction D2 is less than or equal to +/−20 degrees, and is about +/−17 degrees. A FWHM angle of a light intensity distribution in the first direction D1 is greater than or equal to +/−40 degrees. In other words, it exhibits the characteristics of a narrow viewing angle in the second direction D2 (that is, the Y direction).

Through refraction, asymmetric light emission may be achieved, which helps to create a narrower viewing angle in a specific direction. For example, when applied in an automotive head-up display, this may provide the necessary display functions and also prevent interference with the driver's field of view, further enhancing driving safety. In addition, it may be applied to an electronic device that requires a narrow viewing angle for privacy or anti-peeping purposes.

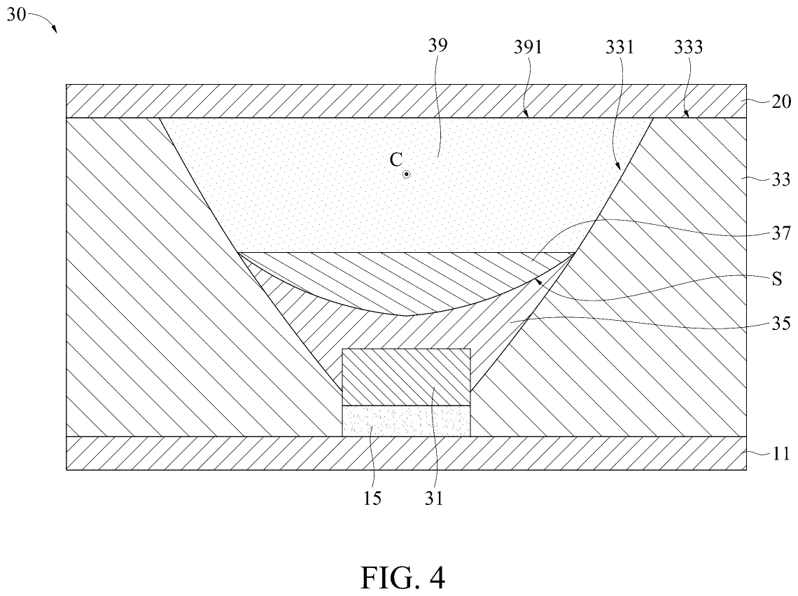

FIG. 4 is a sectional view of a pixel component according to a second embodiment of the present disclosure. Simultaneously referring to FIG. 2, the difference between the second embodiment and the first embodiment mainly exists in that the third refractive region 38 is filled with a third refractive material 39. A refractive index of the third refractive material 39 is is less than the refractive index of the second refractive material 37. In certain embodiments, the refractive index of the third refractive material is 1.2 to 1.6, which may be, for example, 1.5. In addition, in certain embodiments, a top surface 391 of the third refractive material 39 and a first surface 333 of the reflective material 33 are coplanar. In other words, it is possible that the third refractive material 39 is not completely filled in the third refractive region 38, and the refractive index may be adjusted with the third refractive material 39 and air therein.

In addition, as shown in FIGS. 2 and 4, in certain embodiments, a width of the groove 331 decreases from the first surface 333 of the reflective material 33 toward the micro LED 31. More specifically, in certain embodiments, the groove 331 is in a parabolic surface from the first surface 333 of the reflective material 33 toward an edge of the micro LED 31.

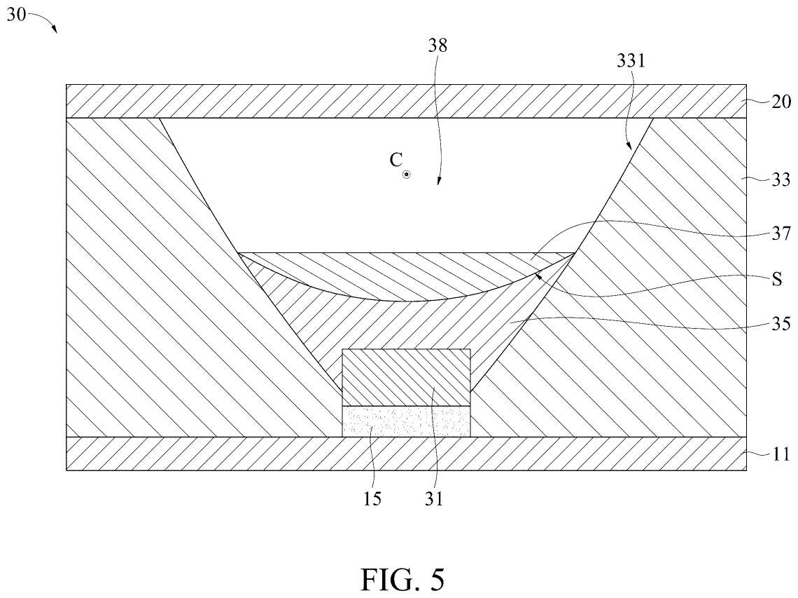

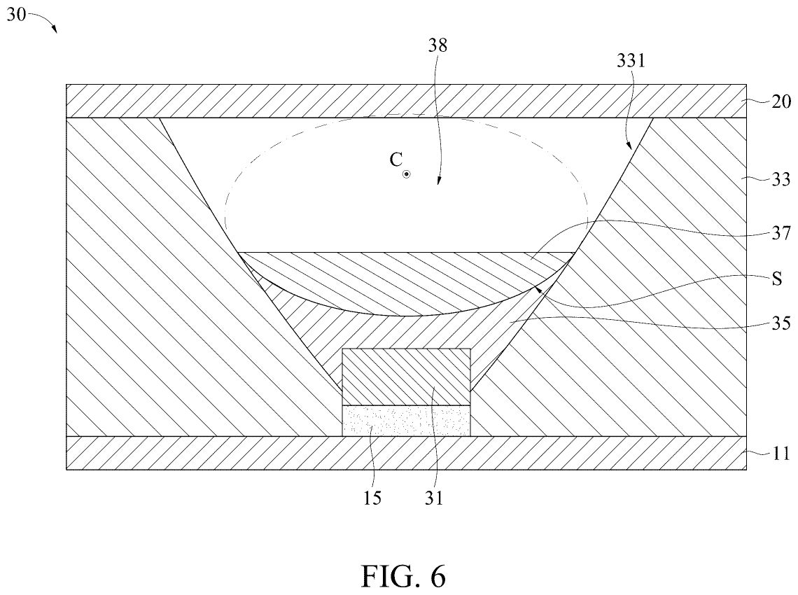

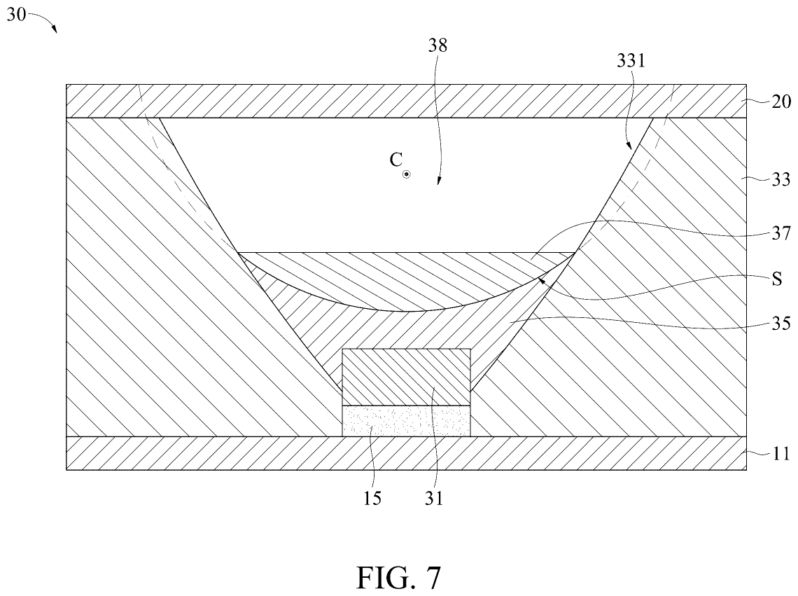

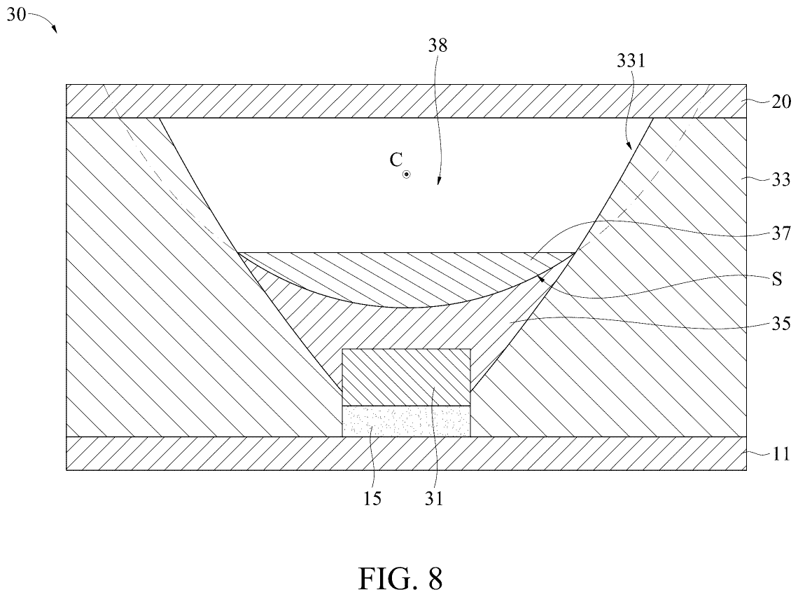

FIG. 5 is a sectional view of a pixel component according to a third embodiment of the present disclosure. FIG. 6 is a sectional view of a pixel component according to a fourth embodiment of the present disclosure. FIG. 7 is a sectional view of a pixel component according to a fifth embodiment of the present disclosure. FIG. 8 is a sectional view of a pixel component according to a sixth embodiment of the present disclosure. As shown in FIGS. 5 to 8, and also referring to FIGS. 2 and 4, the interface between the first refractive material 35 and the second refractive material 37 is a curved surface. Preferably, the curved surface may be a hyperbolic surface as shown in FIGS. 2 and 4, or may be a parabolic surface as shown in FIG. 5, a horizontal elliptical surface as shown in FIG. 6, a spherical surface as shown in FIG. 7, or a vertical elliptical surface as shown in FIG. 8.

In sum, in certain embodiments, by utilizing an anisotropic groove 331 in each pixel component 30, combined with the arrangement of the first refractive material 35 and the second refractive material 37, the light emission of the display device 1 in the first direction D1 and in the second direction D2 may be asymmetrical, allowing the display device to be applied in an electronic device that requires a narrow viewing angle in a specific direction.

The foregoing description of the exemplary embodiments of the invention has been presented only for the purposes of illustration and description and is not intended to be exhaustive or to limit the invention to the precise forms disclosed. Many modifications and variations are possible in light of the above teaching.

The embodiments were chosen and described in order to explain the principles of the invention and their practical application so as to activate others skilled in the art to utilize the invention and various embodiments and with various modifications as are suited to the particular use contemplated. Alternative embodiments will become apparent to those skilled in the art to which the present invention pertains without departing from its spirit and scope. Accordingly, the scope of the present invention is defined by the appended claims rather than the foregoing description and the exemplary embodiments described therein.

What is claimed is:

1. A display device, comprising:
a display substrate, comprising a plurality of pixel components arranged in an array, wherein each of the pixel components comprises a micro light-emitting diode (LED), a reflective material, a first refractive material and a second refractive material, the reflective material is located on the display substrate and is provided with a groove, an upper surface of the micro LED is exposed in the groove, the first refractive material is located in the groove and covers the upper surface of the micro LED, the second refractive material is located in the groove and covers the first refractive material, an interface between the first refractive material and the second refractive material is a curved surface, the groove has a central axis, a depth of the groove decreases by moving away from the central axis, and the central axis is parallel to a first direction; and
a transparent cover, covering the display substrate, wherein a third refractive region is formed between the transparent cover and the second refractive material;
wherein a refractive index of the second refractive material is greater than a refractive index of the first refractive material, and a difference value the refractive index of the first refractive material and the refractive index of the second refractive material is 0.3 to 0.6, and wherein light emission of the display device in the first direction and in a second direction perpendicular to the first direction is asymmetrical.

2. The display device according to claim 1, wherein a width of the groove decreases from a first surface of the reflective material toward the micro LED.

3. The display device according to claim 2, wherein the groove is in a parabolic surface from the first surface of the reflective material toward an edge of the micro LED.

4. The display device according to claim 1, wherein a boundary between first refractive material and the second refractive material is in a hyperbolic surface, a parabolic surface, an elliptical surface, or a spherical surface.

5. The display device according to claim 1, wherein the refractive index of the first refractive material is 1.4 to 1.7.

6. The display device according to claim 5, wherein the refractive index of the second refractive material is 1.4 to 2.0.

7. The display device according to claim 6, wherein the refractive index of the second refractive material is 1.8 to 1.95.

8. The display device according to claim 1, wherein the third refractive region is a cavity.

9. The display device according to claim 1, wherein the third refractive region is filled with a third refractive material, and a refractive index of the third refractive material is less than the refractive index of the second refractive material.

10. The display device according to claim 9, wherein the refractive index of the third refractive material is 1.2 to 1.6.

11. The display device according to claim 9, wherein a top surface of the third refractive material and a first surface of the reflective material are coplanar.

12. The display device according to claim 1, wherein a maximum full width at half maximum (FWHM) angle of a light intensity distribution in the second direction is less than or equal to +/−20 degrees.

13. The display device according to claim 12, wherein a FWHM angle of a light intensity distribution in the first direction is greater than or equal to +/−40 degrees.

14. The display device according to claim 1, wherein each of the pixel components has a first side and a second side, a length of the first side is greater than a length of the second side, the first side is parallel to the first direction, and the second side is parallel to the second direction.

15. The display device according to claim 1, wherein a length of a perpendicular projection of the groove onto the transparent cover in the first direction is greater than a length of the perpendicular projection in the second direction.
